(19) United States
(12) Patent Application Publication
(10) Pub. No.: US 2005/0093153 A1
(43) Pub. Date: May 5, 2005

(54) BGA package with component protection on bottom

(75) Inventor: Sheng-Tsung Liu, Nantz Chiu (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering, Inc.

(21) Appl. No.: 10/973,409

(22) Filed: Oct. 27, 2004

(30) Foreign Application Priority Data
Oct. 31, 2003 (CN) 092130582

(51) Int. Cl. H01L 23/48

(52) U.S. Cl. 257/738; 257/780

(57) ABSTRACT

A ball grid array (BGA) package includes an electronic component mounted on its bottom. Formed on the lower surface of the substrate are the electronic component, a plurality of standoffs and a plurality of solder balls. The standoffs, such as metal balls, are adjacent to the electronic component within the solder balls. The standoffs have a melting point higher than that of the solder balls and offer a uniform standoff height larger than the thickness of the electronic component to control the package collapse to protect the electronic component from contacting a PCB during reflowing process.

### FIELD OF THE INVENTION

The present invention relates to a semiconductor package with an electronic component on its bottom, more particularly to a ball grid array (BGA) package with SMD type passive component.

### BACKGROUND OF THE INVENTION

Ball grid array (BGA) semiconductor packages generally include integrated circuit chips and mounted on a PCB via solder balls. In order to improve quality of electrical signals or increase electrical functions, SMD (surface mount device) type passive components, such as inductors, resistors or capacitors, will be assembled on BGA packages. The passive components are quite cheap and easy to obtain so that there is no need to make the passive components as integral parts of chips or substrates. As disclosed in R.O.C. Taiwan Patent Publication No. 515,063 to Wu et al., an IC package includes a first substrate and a second substrate. The first substrate has a first surface for carrying a chip and a second surface for mounting external terminals, such as solder balls. There are a plurality of passive components disposed on the first surface of the first substrate. The second substrate has an opening to attach to the periphery of the first surface of the first substrate. The first substrate and the second substrate will need larger dimensions to dispose the chip as well as passive components. As a result, the IC package has a larger footprint with an extra cost.

R.O.C. Taiwan Patent Publication No. 459,354 discloses an electronic assembling process. A SMD (Surface Mount Device), such as passive components, is mounted on the active surface of a semiconductor wafer. Usually chips from the wafer with SMD's are electrically connected to a substrate by bonding wires. However, the SMD's protrude from the wafer (chip), the chips with SMD's are difficult to handle, pick & place and transfer.

One of the solutions is that SMD's are mounted on the bottom of conventional PBGA packages accompanied with the solder balls. The solder balls will collapse and the height of the solder balls become uncontrollable during reflowing process. The height variation of ball collapse is about 0.25 mm. Accordingly, the size of the SMD is limited, for example only a small size of SMD type passive component of standard 0201 about 0.3 mm in thickness can be mounted among 0.6 mm or 0.75 mm solder balls, further taking account of the substrate warpage about 0.15 mm. Accordingly, only big solder balls can be used in PBGA in order to mount a small SMD so that it wouldn't be economical.

### SUMMARY

It is a primary object of the present invention to provide a ball grid array package with component protection on bottom. A plurality of standoffs are disposed on a lower surface of a substrate with solder balls. The standoffs surround and are adjacent to the electronic component. The standoffs have a melting point higher than that of the solder balls and offer a standoff height larger than the thickness of the electronic component. Therefore an electronic component with a large dimension can be mounted on the lower surface without being impacted by the collapse of solder balls during reflowing process.

It is a secondary object of the present invention to enhance thermal conductivity and electrical functions. A plurality of standoffs around the electronic component are located between a ball grid array package and a PCB. The standoffs are connected to the dummy pads or the ground layer of the substrate by solder paste.

In one aspect of the present invention, a ball grid array package is provided, which generally includes a substrate, a plurality of solder balls, at least an electronic component and a plurality of standoffs. The substrate has a lower surface with solder balls for SMT connection. The electronic component and the standoffs are disposed on the lower surface, wherein the standoffs are arranged around and adjacent to the electronic component. The standoffs may be copper balls or high lead solder balls. The standoffs have a melting point higher than that of the solder balls and offer a standoff height higher than thickness of the electronic component so as to effectively protect the electronic component from contacting an external printed circuit board.

### DESCRIPTION OF THE DRAWINGS

FIG. 1 is a cross-sectional view of a ball grid array package in accordance with the first embodiment of the present invention.

FIG. 2 is a bottom view of the ball grid array package in accordance with the first embodiment of the present invention.

FIG. 3 is a cross-sectional view illustrating an assembly of the ball grid array package with an external printed circuit board in accordance with the first embodiment of the present invention.

FIG. 4 is a cross-sectional view of a ball grid array package in accordance with the second embodiment of the present invention.

### DETAILED DESCRIPTION OF THE PRESENT INVENTION

Referring to the drawings attached, the present invention will be described by means of the embodiment(s) below.

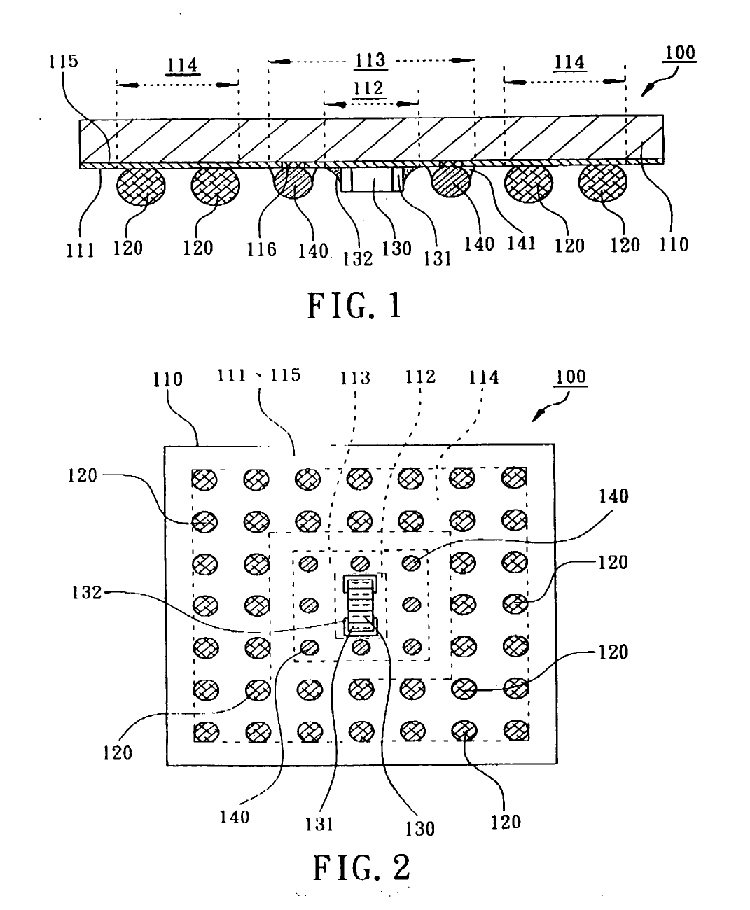

FIGS. 1 and 2 illustrates a first embodiment of ball grid array (BGA) package in accordance with the present invention. The ball grid array package 100 mainly includes a substrate 110, a plurality of solder balls 120, at least an electronic component 130 and a plurality of standoffs 140. In this embodiment, the standoffs 140 are a plurality of copper balls. The substrate 110 has a lower surface 111 mounting with the solder balls 120 for SMT connection. The substrate 110 can be selected from the group consisting of a bumped chip, a CSP (Chip Scale Package), a BT build-up substrate, a ceramic substrate, a wiring film or a PCB. In this embodiment, the substrate 110 is a WLCSP (Wafer Level Chip Scale Package) including integrated circuits. It includes a semiconductor chip and a polymer passivation layer 115 formed on the active surface of the semiconductor chip. In this embodiment, an exposed surface of the polymer passivation layer 115 forms the lower surface 111. The substrate 110 further has a UBM (Under Bump Metallurgy) layer covered by the polymer passivation layer 115 (not showed in the drawings) for connecting the solder balls 120. Referring to FIG. 2, the lower surface 111 of the substrate 110 defines a first region 112 at the center, a second region 113 around the first region 112 and a third region 114 around the second region 113. The second region 113 surrounds the first region 112. Preferably, the first region 112 is formed at the center of the lower surface 111 and the second region 113 is a closed ring of rectangle.

The solder balls 120 are located on the third region 114, preferably the solder balls 120 are arranged in an array. The electronic component 130 is mounted on the first region 112. In this embodiment, the solder balls 120 are eutectic solder, such as 63/37 tin/lead.

The terminals 131 of the electronic component 130 are electrically connected to the substrate 110 by means of the solder material 132 such as solder paste or other conductive materials. Usually the electronic component 130 is one kind of SMD type passive components, for example an inductor, a resistor or a capacitor, to improve electrical functions and act as an electrical protection for the ball grid array package 100.

The standoffs 140 are located on the second region 113. Preferably, the substrate 110 has dummy pads or pads connecting to the ground layer on the second region 113. The standoffs 140 can be bonded to the dummy pads by solder paste 141 or lead-free solder. The standoffs 140 are arranged around and adjacent to the electronic component 130 to protect the electronic component 130. The standoffs 140 may include copper balls or high lead solder balls (5/95 Sn/Pb) as a metal ball between the package 100 and a PCB, which diameters are lying between 0.4 mm and 0.7 mm. In this embodiment, the standoffs 140 have a standoff height higher than the thickness of the electronic component 130 and lower than the diameter of the solder balls 120. Preferably, the standoff height of the standoffs 140 should be at least 0.05 mm larger than the thickness of the electronic component 130 and about 0.05 mm to 0.15 mm smaller than the diameter of the solder balls 120. The standoffs 140 should have a melting point higher than that of the solder balls 120 and have a creep resistance higher than the solder balls 120 at the reflowing temperature, so that the standoffs 140 will maintain their shapes with zero or little deformation relative to the solder balls 120 when the solder balls 120 are reflowed to connect to a PCB 10. Even in repeatedly thermal cycle, the standoffs 140 can keep the electronic component 130 without contact of the PCB 10.

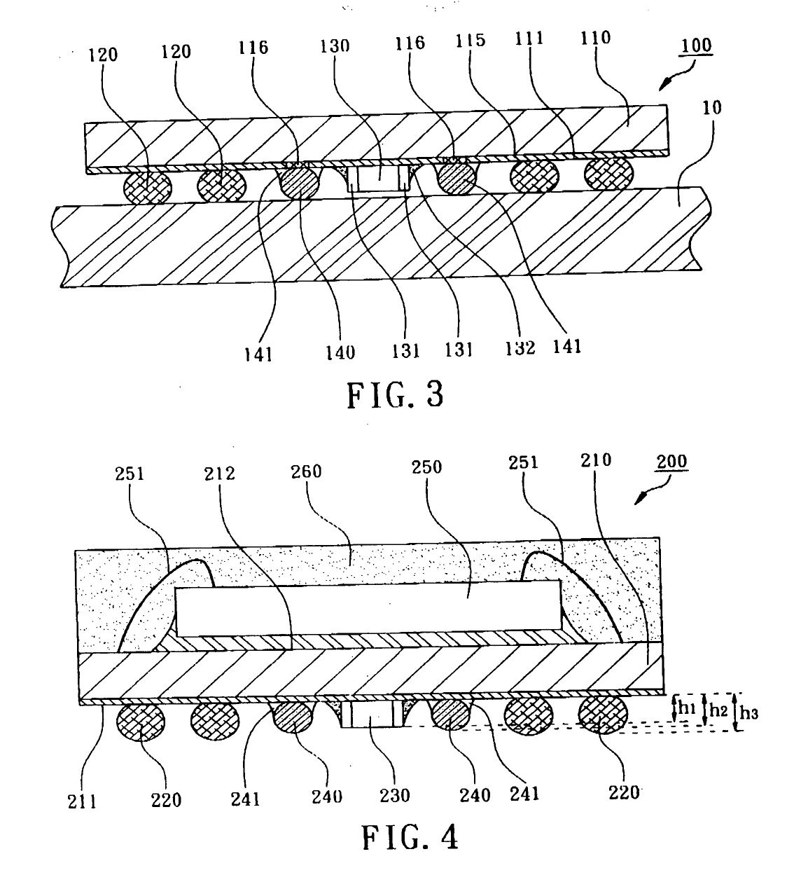

Referring to FIG. 3, when the foregoing ball grid array package 100 is mounted on a printed circuit board (PCB) 10, the solder balls 120 are reflowed to connect with the PCB 10. The standoffs 140 effectively protect the electronic component 130 from contacting the PCB 10 so as to prevent collapse of the ball grid array package 100. The electronic component 130 can be hidden under the ball grid array package 100 without damage.

Alternatively, there is a plurality of metal contact pads 116 formed on the second region 113 and the third region 114 of the substrate 110. The contact pads 116 with electrical transmission are connected with the standoffs 140. Then the standoffs 140 can be connected to the PCB 10 by solder paste for improving heat dissipation and electrical transmission. Considering the dimensions of solder balls 120 and the allowable maximum warpage (about 0.15 mm) of the substrate 110, the diameter of the standoffs 140 should be 0.05 mm to 0.15 mm smaller than the diameter of the solder balls 120 and 0.05 mm larger than the thickness of the electronic component 130. In this embodiment, the diameter of the solder balls 120 is about 0.6 mm and the diameter of the standoffs 140 is between 0.45 mm to 0.55 mm. Therefore, maximum collapse amount of the solder balls 120 can be controlled between 0.05 mm to 0.15 mm. The electronic component 130 having a thickness of between 0.4 mm and 0.5 mm (for example, a passive component according to the standard of 0402) still can be mounted on the lower surface 111 of the substrate 110 without contacting the PCB 10 after SMT. Therefore, utilizing the standoffs 140, the electronic component 130 with a larger dimension can be adapted under the ball grid array package 100. An obvious comparison is showed, only the passive component of standard 0201 about 0.3 mm thickness can be mounted under the bottom surface of a conventional ball grid array package with 0.6 mm solder balls, otherwise the electronic component will be damaged during reflowing. According to the present invention, the passive component of standard 0402 about 0.5 mm thickness can be the electronic component 130 to mount under the lower surface of the ball grid array package 100 with 0.6 mm solder balls and 0.55 mm standoffs 140.

In second embodiment, another ball grid array package 200 is disclosed. Referring to FIG. 4, the ball grid array package 200 mainly includes a substrate 210, a plurality of solder balls 220, at least an electronic component 230 and a plurality of standoffs 240. The standoffs 240 are connected to the substrate 210 by solder pastes 241 or polymer adhesive. In this embodiment, the substrate 210 is a BT substrate having a lower surface 211 and an upper surface 212. A chip 250 is disposed on the upper surface 212 of the substrate 210 and electrically connected to the substrate 210 by a plurality of bonding wires 251 or bumps. An encapsulant 260 may be provided to seal the chip 250 and the bonding wires 251. The solder balls 220 and the electronic component 230 are disposed on the lower surface 211 of the substrate 210. The electronic component 230 is located at the center of the lower surface 211. The solder balls 220 are located on the periphery of the lower surface 211 and arranged in an array. The standoffs 240 are arranged around and adjacent to the electronic component 230, also away from the array of the solder balls 220. Preferably, the standoffs 240 have a standoff height h2 larger than the thickness h1 of the electronic component 230 but smaller than the height h3 of the solder balls 220. The standoffs 240 has a melting point higher than that of the solder balls 220 to resist deformation of the solder balls 220 during reflowing.

While the present invention has been particularly illustrated and described in detail with respect to the preferred embodiments thereof, it will be clearly understood by those skilled in the art that various changed in form and details may be made without departing from the spirit and scope of the present invention.

1. A ball grid array package comprising:
a substrate having a lower surface defining a first region, a second region and a third region,
wherein the second region is formed between the first region and the third region;
at least an electronic component mounted on the first region;
a plurality of solder balls located on the third region; and
a plurality of standoffs located on the second region, the standoffs having a standoff height larger than the thickness of the electronic component.

2. The package in accordance with claim 1, wherein the standoffs have a melting point higher than that of the solder balls.

3. The package in accordance with claim 1, wherein the standoffs are adjacent to the electronic component.

4. The package in accordance with claim 1, wherein the electronic component is a SMD type passive component.

5. The package in accordance with claim 1, wherein the standoffs are metal balls.

6. The package in accordance with claim 5, wherein the substrate includes a plurality of dummy pads on the second region, the metal balls are connected to the dummy pads by solder paste.

7. The package in accordance with claim 6, wherein the metal balls are copper balls.

8. The package in accordance with claim 5, wherein the metal balls have a lead percentage higher than that of the solder balls on the third region.

9. The package in accordance with claim 8, wherein the solder balls on the third region are tin-lead eutectic.

10. The package in accordance with claim 1, wherein the standoff height of the standoffs is at least 0.05 mm larger than the thickness of the electronic component.

11. The package in accordance with claim 1, wherein the standoff height of the standoffs is between 0.4 mm and 0.7 mm.

12. The package in accordance with claim 1, wherein the solder balls on the third region have a diameter larger than the standoff height.

13. The package in accordance with claim 1, wherein the standoff height is 0.05 mm to 0.15 mm smaller than the diameter of the solder balls.

14. The package in accordance with claim 1, wherein the substrate is selected from the group consisting of a bumped chip, a CSP (Chip Scale Package), a BT build-up substrate, a ceramic substrate, a wiring film and a PCB.

15. The package in accordance with claim 1, further comprising a chip attached to the upper surface of the substrate.

16. The package in accordance with claim 1, wherein the solder balls are arranged in an array, the standoffs are positioned away from the array.

17. An electronic board assembly comprising:
a printed circuit board having a connection surface;
a substrate having a lower surface defining a first region;
at least an electronic component mounted on the first region;
a plurality of solder balls bonding the printed circuit board and the substrate; and
a plurality of standoffs being located between the lower surface and the connection surface, the standoffs being adjacent to the first region and having a standoff height such that the electronic component doesn't contact the printed circuit board.

18. The assembly in accordance with claim 17, wherein the standoffs have a melting point higher than that of the solder balls.

19. The assembly in accordance with claim 18, wherein the standoffs are metal balls.

20. The assembly in accordance with claim 19, further comprising a solder paste connecting the metal balls to the printed circuit board.

21. The assembly in accordance with claim 19, wherein the metal balls are copper balls or high lead solder balls.

22. The assembly in accordance with claim 17, wherein the standoffs have a uniform standoff height between 0.4 mm and 0.7 mm.

23. A ball grid array package comprising:
a substrate having a lower surface;
a plurality of first metal balls located on the lower surface;
a plurality of second metal balls located on the lower surface within the first metal balls; and
at least an electronic component mounted on the lower surface within the second metal balls;
wherein the diameter of the second metal balls is smaller than that of the first metal balls and larger than the thickness of the electronic component, the melting point of the second metal balls is higher than that of the first metal balls.

24. The package in accordance with claim 23, wherein the diameter of the second metal balls is between 0.4 mm and 0.7 mm.

25. A ball grid array package comprising:
a substrate having a lower surface defining a central region;
at least an electronic component mounted on the central region;
a plurality of solder balls located on the lower surface; and
a plurality of metal standoffs located on the lower surface and adjacent to the electronic component;
wherein the standoffs have a creep resistance higher than the solder balls.

26. The package in accordance with claim 25, wherein the standoffs are metal balls and electrically connected to the ground layer of the substrate.
